(19) United States
(12) Patent Application Publication
(10) Pub. No.: US 2021/0122301 A1
(43) Pub. Date: Apr. 29, 2021

(54) VEHICLE DECORATIVE PLATE AND FORMING METHOD THEREOF

(71) Applicant: TONG YANG INDUSTRY CO., LTD., TAINAN CITY (TW)

(72) Inventors: YI-KUAN LIN, TAINAN CITY (TW); PEI-YU WANG, TAINAN CITY (TW); FU-CHIEH HU, TAINAN CITY (TW)

(21) Appl. No.: 17/004,256

(22) Filed: Aug. 27, 2020

(30) Foreign Application Priority Data
Oct. 24, 2019 (TW) 108138446

(51) Int. Cl. B60R 13/00; B60R 13/04; C23C 14/58; C23C 14/34; C23C 14/24; C23C 14/06; C23C 14/08; C23C 14/10

(52) U.S. Cl. CPC B60R 13/005; B60R 13/04; C23C 14/5873; C23C 14/34; C23C 14/10; C23C 14/0652; C23C 14/081; C23C 14/083; C23C 14/24

(57) ABSTRACT

A vehicle decorative plate and a forming method thereof are disclosed. The vehicle decorative plate can be made into a vehicle emblem, a vehicle grille, a vehicle front bumper trim, a vehicle door trim or a vehicle rear bumper trim. The vehicle decorative plate includes a curved substrate, a display layer, and a curved covering. After the curved substrate is coated with a plating layer, unnecessary parts of the plating layer are removed by laser engraving to process the plating layer into the display layer. The curved covering is attached to the curved substrate and covers the display layer. At least one of the curved substrate and the curved covering is transparent or semi-transparent.

### FIELD OF THE INVENTION

The present invention relates to a vehicle decorative plate and a forming method thereof, and more particularly to a vehicle decorative plate using laser engraving to process the pattern of a display layer.

### BACKGROUND OF THE INVENTION

Referring to FIG. 5 through FIG. 7, a conventional vehicle decorative plate, such as a vehicle emblem (A), comprises a substrate (A1), an anti-scratch layer (A2), a display layer (A3), a metal plating layer (A4), a protective paint layer (A5), and a protective covering (A6).

First, the outer surface of the substrate (A1) is coated with the anti-scratch layer (A2), and then the graphics of the display layer (A3) are printed on the inner surface of the substrate (A1) with inks by screen printing, transfer printing, hot stamping, etc. Then, the metal plating layer (A4) is evaporated or sputtered on the display layer (A3). After the protective paint layer (A5) is coated, it is covered with the protective covering (A6). The display layer (A3) refers to the part where the ink shields the substrate (A1), and the graphics, patterns or characters can be directly displayed by the ink of the display layer (A3). Alternatively, the display layer (A3) may be a shielded part formed by the ink on the substrate (A1). The non-shielded part on the substrate (A1) shows the metallic texture of the metal plating layer (A4), and the metal plating layer (A4) forms the graphics, patterns or characters.

However, the display layer (A3) formed by ink printing is only suitable for a decorative plate with a flat or slightly curved surface. When the decorative plate is in a large curved shape, the display layer (A3) formed by ink printing has the following problems:

1. When using screen printing, printing on curved surfaces, such as printing on concave surfaces, may not be able to completely transfer graphics, resulting in missing parts. Therefore, when the radius of curvature of the concave surface is too large or there is a special shape, screen printing cannot be used.

2. When using transfer printing, printing on curved surfaces sometimes produces burrs on the edges of the graphics or broken graphics and other problems, resulting in poor appearance of the graphics.

3. When hot stamping is used for curved surface printing, it is easy to cause poor appearance, such as burrs on the edges of graphics or broken graphics. Besides, hot stamping requires the substrate to undergo a high temperature and high pressure process, which is likely to cause stress and cracks on the curved substrate.

Taiwan Utility Model Publication No. M544436 discloses an automotive interior light-emitting plate. The opaque ink is removed by laser engraving to engrave a light-pervious pattern on an automotive decorative plate. However, it is used for making automotive flat decorative plates.

Taiwan Patent No. 479120 discloses a method for manufacturing a vehicle side view mirror with an indicator function and a vehicle side view mirror manufactured by this method. Color paint is sprayed on the shell of the side view mirror, and then part of the color paint is removed by laser engraving to form a transparent display pattern.

The above-mentioned cases use laser engraving to remove opaque ink or color paint. However, the high-temperature laser processing may change the quality of the ink or paint and cause the color to change, and the desired color cannot be presented and the product quality is not uniform.

### SUMMARY OF THE INVENTION

The primary object of the present invention is to provide a vehicle decorative plate, without using ink to present a display layer. The vehicle decorative plate comprises a curved substrate, a display layer, and a curved covering. After the curved substrate is coated with a plating layer, unnecessary parts of the plating layer are removed by laser engraving to process the plating layer into the display layer. The curved covering is attached to the curved substrate and covers the display layer. At least one of the curved substrate and the curved covering is transparent or semi-transparent.

The present invention further provide a method for forming a vehicle decorative plate, comprising: applying a plating layer to a curved substrate; removing unnecessary parts of the plating layer by laser engraving to process the plating layer into a display layer; attaching a curved covering to the curved substrate for covering the display layer, wherein at least one of the curved substrate and the curved covering is transparent or semi-transparent.

Preferably, the curved substrate is transparent or semi-transparent and has a convex display surface and a concave back surface, and the display layer is located on the concave back surface. Preferably, the curved substrate has an anti-scratch layer thereon, and the anti-scratch layer is located opposite the display layer.

Preferably, the curved substrate has a convex display surface and a concave back surface, the display layer is located on the convex display surface, and the curved covering is transparent or semi-transparent. Preferably, the curved covering has an anti-scratch layer thereon, and the anti-scratch layer is located opposite the display layer.

Preferably, the display layer is coated with a protective paint layer and then covered with the curved covering by means of injection or adhesion.

Preferably, the vehicle decorative plate is any one of a vehicle emblem, a vehicle grille, a vehicle front bumper trim, a vehicle door trim and a vehicle rear bumper trim.

Preferably, the plating layer includes a main metal layer and a metal or metal-like oxide film layer outside the main metal layer. The material of the main metal layer is any one of In, Cr, Al, Sn or an alloy thereof. The metal or metal-like oxide film layer is any one of SiₓO_{y}, TiₓO_{y}, AlₓO_{y} and SiₓN_{y}.

Preferably, the plating layer has a thickness between 10 nanometers and 150 nanometers, and the protective paint layer has a thickness between 15 microns and 100 microns.

The above technical features have the following advantages:

1. The conventional vehicle decorative plate uses ink printing to print graphics, and then a metal plating layer is disposed on the ink graphics by evaporation or sputtering; or uses laser engraving to remove the opaque ink to display the graphics. The vehicle decorative plate of the present invention does not use ink at all, and it directly engraves the graphics of the display layer on the metal plating layer, without the need to display the graphics using ink, and solves the problem that the ink is deteriorated to cause color difference due to high temperature.

2. The thickness of the display layer of the present invention is approximately between 10 nanometers and 150 nanometers, and the display layer is light-pervious, so that the vehicle decorative plate can present a brighter visual experience.

3. Laser engraving can engrave the complete graphics of the display layer on the curved substrate, especially on the concave back surface, which solves the problem that the screen printing on the curved surface cannot transfer the graphics completely.

4. Using laser engraving on the curved substrate to process the graphics of the display layer can make the graphics of the display layer have a smooth and complete edge, so as to solve the problem that the curved surface printing of transfer printing, hot stamping and screen printing produces burrs on the edges of the graphics or broken graphics (i.e., incomplete printed graphics) and other issues.

4. Using laser engraving on the curved substrate to process the graphics of the display layer can prevent the graphics of the display layer from cracking, and solve the problem that the curved surface printing by hot stamping causes stress or cracks in the display graphics.

### BRIEF DESCRIPTION OF THE DRAWINGS

FIG. 1 is a schematic view according to an embodiment of the present invention, wherein the vehicle decorative plate is a vehicle emblem;

FIG. 2 is a structural schematic view of the vehicle decorative plate in one form;

FIG. 3 is a flow chart of manufacturing the vehicle decorative plate of the present invention;

FIG. 4 is a structural schematic view of the vehicle decorative plate in another form;

FIG. 5 is a schematic view of a conventional vehicle decorative plate that that takes a vehicle emblem as example;

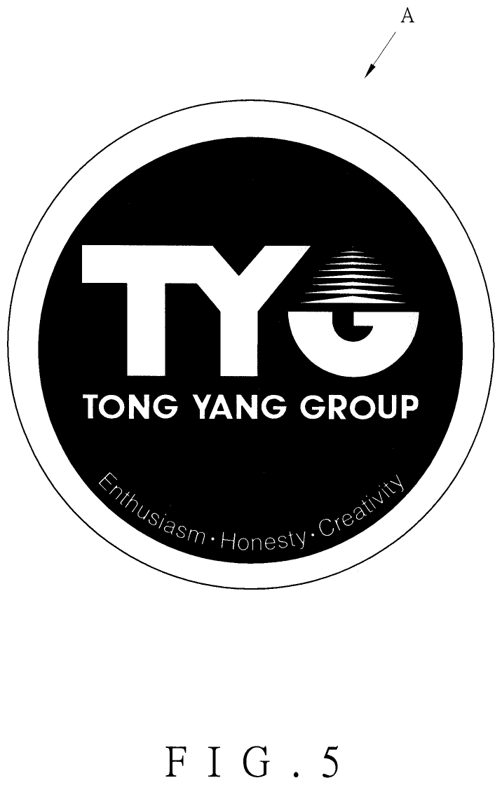

FIG. 6 is a structural schematic view of the conventional vehicle decorative plate; and

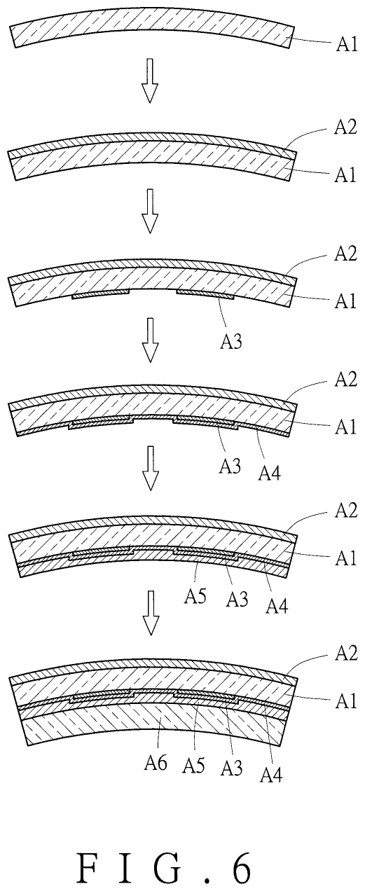

FIG. 7 is a flow chart of manufacturing the conventional vehicle decorative plate.

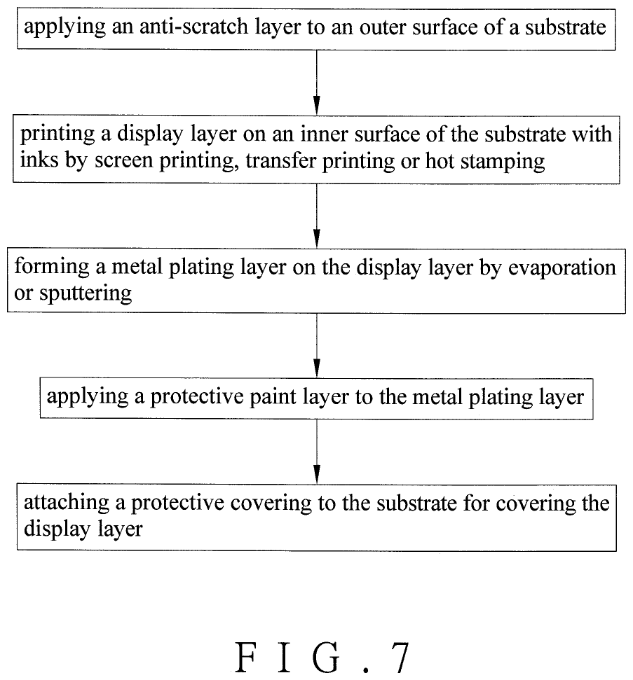

### DETAILED DESCRIPTION OF THE PREFERRED EMBODIMENTS

Embodiments of the present invention will now be described, by way of example only, with reference to the accompanying drawings.

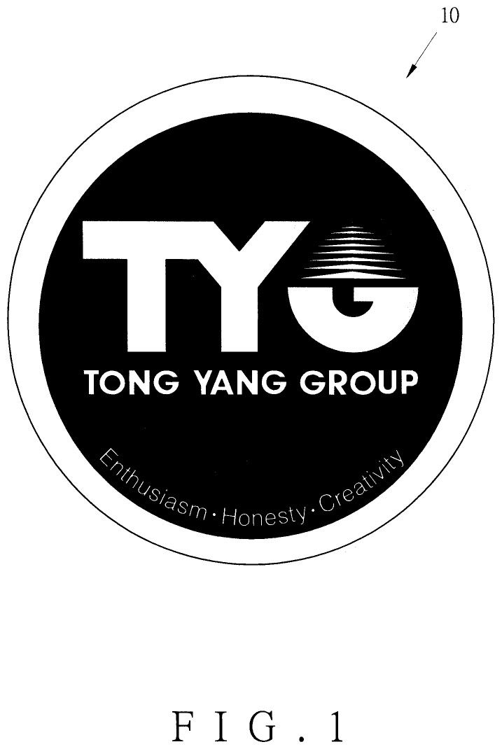

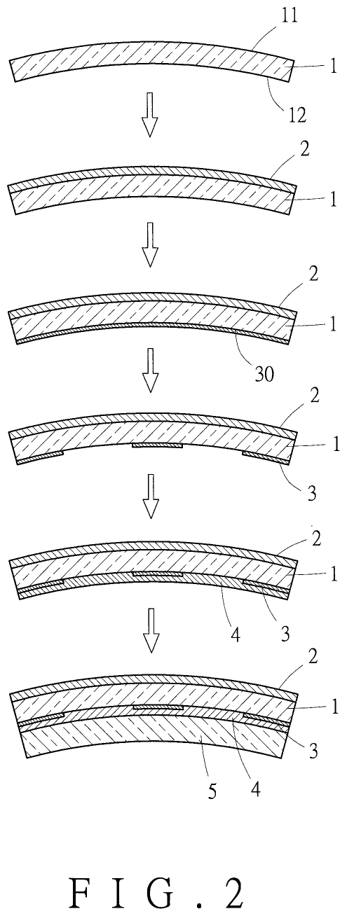

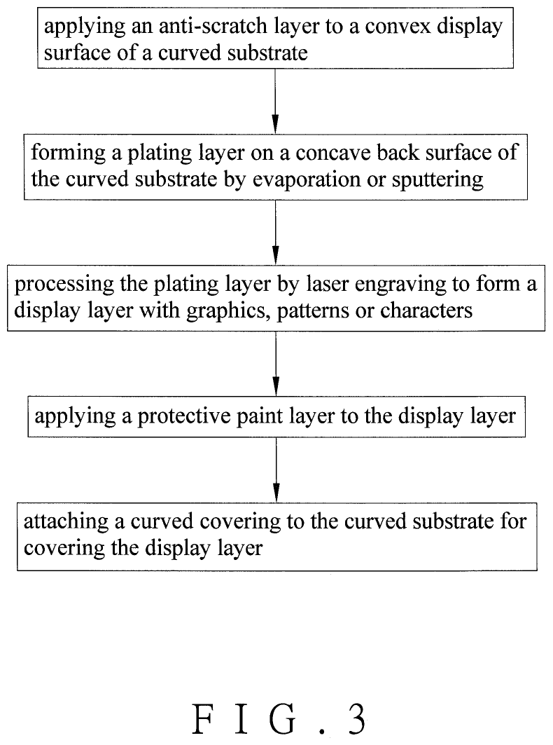

Referring to FIG. 1 through FIG. 3, the vehicle decorative plate of this embodiment is a vehicle emblem (10) as an example, but not limited to the vehicle emblem (10). The vehicle decorative plate may be made into a vehicle grille, a vehicle front bumper trim, a vehicle door trim, a vehicle rear bumper trim, etc. The vehicle emblem (10) includes a curved substrate (1), an anti-scratch layer (2), a display layer (3), a protective paint layer (4), and a curved covering (5).

The curved substrate (1) is transparent or semi-transparent and has a convex display surface (11) and a concave back surface (12). The convex display surface (11) of the curved substrate (1) is coated with the anti-scratch layer (2). Since the convex display surface (11) is exposed to the environment for displaying the display layer (3) after the production is completed, the anti-scratch layer (2) coated on the convex display surface (11) can reduce the wear of the convex display surface (11). Afterwards, a plating layer (30) is coated on the concave back surface (12) by evaporation or sputtering, and then the unnecessary parts of the plating layer is removed by laser engraving to process the plating layer into the display layer (3). The display layer (3) is configured to display the graphics, patterns or characters of the vehicle emblem (10). The parameters of laser engraving are modified according to different metal plating. Laser engraving is a conventional technology, so it will not be described hereafter. Then, the display layer (3) is coated with the protective paint layer (4) to prevent the display layer (3) from peeling off or to slow down its oxidation. After that, the curved covering (5) is attached to the curved substrate (1) for covering the display layer (3) by means of injection or adhesion. The curved substrate (1) is transparent or semi-transparent, so the graphics, patterns or characters of the display layer (3) can be displayed.

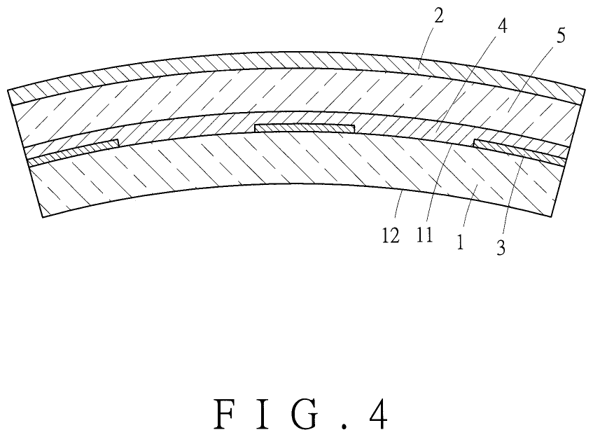

Referring to FIG. 4, in addition to fabricating the display layer (3) on the concave back surface (12) of the curved substrate (1), the display layer (3) may be fabricated on the convex display surface (11) of the curved substrate (1). For example, in FIG. 4, a plating layer is coated on the convex display surface (11) by evaporation or sputtering, and then the unnecessary parts of the plating layer is removed by laser engraving to process the plating layer into the display layer (3). Then, the display layer (3) is coated with the protective paint layer (4) to prevent the display layer (3) from peeling off or to slow down its oxidation. After that, the curved covering (5) is attached to the curved substrate (1) for covering the display layer (3). Since the curved covering (5) is exposed to the environment for displaying the display layer (3), the anti-scratch layer (2) is coated on the curved covering (5). The curved covering (5) is transparent or semi-transparent, so the graphics, patterns or characters of the display layer (3) can be displayed.

Furthermore, the thickness of the plating layer (30) is approximately between 10 nanometers and 150 nanometers, and the thickness of the plating layer (30) is preferably between 40 nanometers and 100 nanometers. The thickness of the protective paint layer (4) used for protecting the display layer (3) is between 15 microns and 100 microns, preferably between 40 microns and 60 microns, and may be transparent or opaque, so as to present a more varied visual experience. Preferably, the plating layer (30) further includes a metal or metal-like oxide film layer, such as SiₓO_{y}, TiₓO_{y}, AlₓO_{y}, SiₓN_{y} and the like to form a protective layer for protecting the main metal layer during evaporation or sputtering. The material of the main metal layer is any one of In, Cr, Al, Sn or their alloys.

The vehicle decorative plate of the present invention does not use ink at all, and directly engraves the graphics of the display layer (3) on the metal plating layer, without the need to generate the graphics using ink, and solves the problem that the laser engraving ink is deteriorated to cause color difference due to high temperature. Further, it does not use screen printing, transfer printing, hot stamping and other printing methods to transfer the graphics of the display layer (3), so there will be no burrs or cracks in the graphics or incomplete transfer. The curved substrate of the present invention may be a regular curved surface with a single curvature, or an irregular curved surface with any curvature.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A vehicle decorative plate, comprising:
a curved substrate;
a display layer, after the curved substrate is coated with a plating layer, unnecessary parts of the plating layer being removed by laser engraving to process the plating layer into the display layer;
a curved covering, attached to the curved substrate and covering the display layer, at least one of the curved substrate and the curved covering being transparent or semi-transparent.

2. The vehicle decorative plate as claimed in claim 1, wherein the curved substrate is transparent or semi-transparent and has a convex display surface and a concave back surface, and the display layer is located on the concave back surface.

3. The vehicle decorative plate as claimed in claim 2, wherein the curved substrate has an anti-scratch layer thereon, and the anti-scratch layer is located opposite the display layer.

4. The vehicle decorative plate as claimed in claim 1, wherein the curved substrate has a convex display surface and a concave back surface, the display layer is located on the convex display surface, and the curved covering is transparent or semi-transparent.

5. The vehicle decorative plate as claimed in claim 4, wherein the curved covering has an anti-scratch layer thereon, and the anti-scratch layer is located opposite the display layer.

6. The vehicle decorative plate as claimed in claim 1, wherein the display layer is coated with a protective paint layer and then covered with the curved covering.

7. The vehicle decorative plate as claimed in claim 1, wherein the vehicle decorative plate is any one of a vehicle emblem, a vehicle grille, a vehicle front bumper trim, a vehicle door trim and a vehicle rear bumper trim.

8. The vehicle decorative plate as claimed in claim 1, wherein the plating layer includes a main metal layer and a metal or metal-like oxide film layer outside the main metal layer.

9. The vehicle decorative plate as claimed in claim 8, wherein the metal or metal-like oxide film layer is any one of SiₓO_{y}, TiₓO_{y}, AlₓO_{y} and SiₓN_{y}.

10. A method for forming a vehicle decorative plate, comprising:
applying a plating layer to a curved substrate;
removing unnecessary parts of the plating layer by laser engraving to process the plating layer into a display layer;
attaching a curved covering to the curved substrate for covering the display layer, wherein at least one of the curved substrate and the curved covering is transparent or semi-transparent.

11. The method as claimed in claim 10, wherein the plating layer has a thickness between 10 nanometers and 150 nanometers.

12. The method as claimed in claim 10, wherein the display layer is coated with a protective paint layer and then covered with the curved covering, and the protective paint layer has a thickness between 15 microns and 100 microns.
